(19) United States
(12) Patent Application Publication
(10) Pub. No.: US 2019/0055625 A1
(43) Pub. Date: Feb. 21, 2019

(54) HOT EXTRUDED MATERIAL FOR CYLINDRICAL SPUTTERING TARGET AND METHOD OF MANUFACTURING CYLINDRICAL SPUTTERING TARGET

(71) Applicant: MITSUBISHI MATERIALS CORPORATION, Tokyo (JP)

(72) Inventors: Michiaki Ohto, Iwaki-shi (JP); Satoshi Kumagai, Osaka (JP); Akira Sakurai, Osaka (JP)

(73) Assignee: MITSUBISHI MATERIALS CORPORATION, Tokyo (JP)

(21) Appl. No.: 16/081,181

(22) PCT Filed: Sep. 26, 2017
(86) PCT No.: PCT/JP2017/034742

§ 371 Date: Aug. 30, 2018

(30) Foreign Application Priority Data
Oct. 7, 2016 (JP) 2016-199009

(51) Int. Cl. C22C 9/01; H01J 37/34; C23C 14/34; H01L 21/285; C22F 1/08

(52) U.S. Cl. CPC C22C 9/01; H01J 37/3426; C22F 1/08; H01L 21/285; C23C 14/3414

(57) ABSTRACT

A hot extruded material for a cylindrical sputtering target is provided, in which a purity of copper is in a range of 99.99 mass % to 99.9995 mass %, an Al content is 0.5 mass ppm or lower, a Si content is 1 mass ppm or lower, a C content is 1 mass ppm or lower, an O content is 2 mass ppm or lower, a H content is 1 mass ppm or lower, and a S content is 5 mass ppm or lower, and an average crystal grain size measured at 36 positions in total is in a range of 10 μm to 110 μm and a Vickers hardness measured at the 36 positions in total is in a range of 40 Hv to 100 Hv, the 36 positions being selected by obtaining three cross-sections perpendicular to an axis O direction from one end portion, an intermediate portion, and another end portion in the axis O direction, setting four positions in a peripheral direction from each of the three cross-sections, and setting three positions in each of the four positions, the three positions including a surface part, a radially ¼ position from the surface part, and a radially ½ position from the surface part.

### TECHNICAL FIELD

The present invention relates to a hot extruded material for a cylindrical sputtering target that is a material of a cylindrical sputtering target used during sputtering of a thin film formed of copper, and a method of manufacturing a cylindrical sputtering target.

Priority is claimed on Japanese Patent Application No. 2016-199009, filed on Oct. 7, 2016, the content of which is incorporated herein by reference.

### BACKGROUND ART

In the related art, Al or an Al alloy is widely used as a wiring film for a flat panel display such as a liquid crystal or organic EL panel or for a touch panel. Recently, the size (width) and thickness of a wiring film have been reduced, and thus a wiring film having a lower specific resistance than that in the related art has been required.

Therefore, along with the reduction in size and thickness of the wiring film, a wiring film formed of copper that is a material having a lower specific resistance than Al or an Al alloy is provided.

In a case where a wiring film (thin film) formed of copper is formed on a substrate, a sputtering method using a sputtering target is typically adopted.

As the sputtering target, for example, a flat sputtering target described in Patent Document 1, or a cylindrical sputtering target described in Patent Documents 2 and 3 is proposed.

An outer peripheral surface of the cylindrical sputtering target is a sputtering surface, and sputtering is performed while rotating the cylindrical sputtering target. Therefore, the cylindrical sputtering target is more suitable for continuous film formation as compared to a case where the flat sputtering target is used, and has an advantageous effect in that the efficiency in use of the target is excellent.

### CITATION LIST

### Patent Literature

[Patent Document 1] Japanese Patent No. 4974198

[Patent Document 2] Japanese Unexamined Patent Application, First Publication No. 2013-057112

[Patent Document 3] Japanese Unexamined Patent Application, First Publication No. 2013-185238

### DISCLOSURE OF INVENTION

### Technical Problem

As described in Patent Documents 2 and 3, the cylindrical sputtering target is manufactured using a manufacturing method including a melting and casting step, a hot working (extrusion) step, a cold working (expansion) step, and a heat treatment step.

Recently, the size of a substrate has increased, and a longer lifetime than that in the related art has been required for the cylindrical sputtering target.

In order to improve the lifetime of the cylindrical sputtering target, it is necessary to manufacture a thick material having a large difference between an outer diameter and an inner diameter.

In a case where cold working (expansion) is performed as described in Patent Documents 2 and 3, warping or bending occurs during working. Therefore, in order to correct warping or bending, it is necessary to cut an outer peripheral surface or an inner peripheral surface. Therefore, it is difficult to provide a thick cylindrical sputtering target.

Further, since a hot extruded material formed of pure copper is relatively soft, bending or thickness deviation is likely to occur. In addition, since the recrystallization temperature is low, the progress of recrystallization varies in an axis direction, and characteristics are not stable. Therefore, a hot extruded material cannot be used as a sputtering target without performing cold working.

In addition, in a case where a film is formed using a sputtering target, foreign matter in the sputtering target may cause abnormal discharge (arcing) to occur. Therefore, there may be a case where a uniform wiring film cannot be formed. Abnormal discharge is a phenomenon in which a much higher current than that during normal sputtering suddenly flows such that abnormally large discharge occurs. In a case where this abnormal discharge occurs, particle formation may occur, or the thickness of a wiring film may be uneven. Accordingly, it is desirable to avoid abnormal discharge as much as possible during film formation.

The present invention has been made in consideration of the above-described circumstances, and an object thereof is to provide a thick and long-life hot extruded material for a cylindrical sputtering target with which the occurrence of abnormal discharge is suppressed such that a film can be stably formed, and a method of manufacturing a cylindrical sputtering target using the hot extruded material for a cylindrical sputtering target.

### Solution to Problem

In order to achieve the object, according to the present invention, a hot extruded material for a cylindrical sputtering target is provided, in which a purity of copper is in a range of 99.99 mass % to 99.9995 mass %, an Al content is 0.5 mass ppm or lower, a Si content is 1 mass ppm or lower, a C content is 1 mass ppm or lower, an O content is 2 mass ppm or lower, a H content is 1 mass ppm or lower, and a S content is 5 mass ppm or lower, and an average crystal grain size measured at 36 positions in total is in a range of 10 μm to 110 μm and a Vickers hardness measured at the 36 positions in total is in a range of 40 Hv to 100 Hv, the 36 positions being selected by obtaining three cross-sections perpendicular to an axis direction from one end portion, an intermediate portion, and another end portion in the axis direction, setting four positions in a peripheral direction from each of the three cross-sections, and setting three positions in each of the four positions, the three positions including a surface part, a radially ¼ position from the surface part, and a radially ½ position from the surface part.

The purity of copper in the present invention is a numerical value excluding gas components such as O, H, N, S, and C.

In the hot extruded material for a cylindrical sputtering target according to the present invention having the above-described configuration, an average crystal grain size measured at 36 positions in total (three cross-section×four positions in a peripheral direction×three positions=36 positions) in a range of 10 μm to 110 μm and a Vickers hardness measured at the 36 positions in total is in a range of 40 Hv to 100 Hv, the 36 positions being selected by obtaining three cross-sections perpendicular to an axis direction from one end portion, an intermediate portion, and another end portion in the axis direction, setting four positions in a peripheral direction from each of the three cross-sections, and setting three positions in each of the four positions, the three positions including a surface part, a radially ¼ position from the surface part, and a radially ½ position from the surface part. Therefore, there is no variation in crystal grain size and hardness in the axis direction and the radial direction, and the hot extruded material for a cylindrical sputtering target can be used as a cylindrical sputtering target only after performing machining thereon.

In addition, cold working (expansion) is not necessary. Therefore, a thick cylindrical sputtering target can be obtained, and the lifetime thereof can be increased.

In addition, the Al content is 0.5 mass ppm or lower, the Si content is 1 mass ppm or lower, the C content is 1 mass ppm or lower, the O content is 2 mass ppm or lower, the H content is 1 mass ppm or lower, and the S content is 5 mass ppm or lower. Therefore, the occurrence of abnormal discharge caused by impurities can be reliably reduced.

In the hot extruded material for a cylindrical sputtering target according to the present invention, it is preferable that a total content of one element or two or more elements selected from the group consisting of Ag, As, Pb, Sb, Bi, Cd, Sn, Ni, and Fe be in a range of 10 mass ppm to 50 mass ppm.

In this case, the total content of one element or two or more elements selected from the group consisting of Ag, As, Pb, Sb, Bi, Cd, Sn, Ni, and Fe is 10 mass ppm or higher. Therefore, the crystal grain size can be reduced, and a variation in average crystal grain size and Vickers hardness can be suppressed. On the other hand, the total content of one element or two or more elements selected from the group consisting of Ag, As, Pb, Sb, Bi, Cd, Sn, Ni, and Fe is limited to be 50 mass ppm or lower. Therefore, the occurrence of abnormal discharge caused by the elements can be reliably reduced.

In addition, in the hot extruded material for a cylindrical sputtering target according to the present invention, it is preferable that a weight ratio of acid-insoluble residues be 1.5 mass ppm or lower and the number of acid-insoluble residues having a grain size of 5 μm or more be 15000 residues/Cu 1 g or less.

In this case, the weight ratio of acid-insoluble residues is in a range of 0.2 mass ppm to 1.5 mass ppm, and the number of acid-insoluble residues having a grain size of 5 μm or more is limited to be 15000 residues/Cu 1 g or less. Therefore, particle formation can be suppressed during film formation.

Further, in the hot extruded material for a cylindrical sputtering target according to the present invention, it is preferable that an outer diameter be 140 mm to 200 mm, an inner diameter be 80 mm to 140 mm, a length be 900 mm to 4000 mm, and a maximum bending amount be 1.5 mm or less.

In this case, the outer diameter is 140 mm to 200 mm, and the inner diameter is 80 mm to 140 mm. Therefore, a thick, long-life cylindrical sputtering target can be manufactured. In addition, the maximum bending amount is 1.5 mm or less. Therefore, a reduction in thickness caused by cutting can be suppressed.

According to the present invention, a method of manufacturing a cylindrical sputtering target is provided, including: a melting and casting step of obtaining an ingot in which a purity of copper is 99.99 mass % to 99.9995 mass %, an Al content is 0.5 mass ppm or lower, a Si content is 1 mass ppm or lower, a C content is 1 mass ppm or lower, an O content is 2 mass ppm or lower, a H content is 1 mass ppm or lower, and a S content is 5 mass ppm or lower; a hot extrusion step of performing hot extrusion on the ingot to obtain a hot extruded material for a cylindrical sputtering target; and a machining step of performing machining on the hot extruded material for a cylindrical sputtering target.

In the method of manufacturing a cylindrical sputtering target according to the embodiment having the above-described configuration machining is performed on the hot extruded material for a cylindrical sputtering target obtained in the hot extrusion step. In this method, a cooling step is not necessary, and the manufacturing costs can be reduced. In addition, bending or warping caused by a cooling step does not occur, the inner peripheral surface and the outer peripheral surface of the hot extruded material for a cylindrical sputtering target is not cut more than necessary, and thus a thick cylindrical sputtering target can be obtained.

### Advantageous Effects of Invention

According to the present invention, it is possible to provide a thick and long-life hot extruded material for a cylindrical sputtering target with which the occurrence of abnormal discharge is suppressed such that a film can be stably formed, and a method of manufacturing a cylindrical sputtering target using the hot extruded material for a cylindrical sputtering target.

### BRIEF DESCRIPTION OF DRAWINGS

FIG. 1 is a schematic diagram showing a hot extruded material for a cylindrical sputtering target according to an embodiment of the present invention. FIG. 1(a) is a cross-sectional view perpendicular to an axis direction, and FIG. 1(b) is a side view.

FIG. 2 is a diagram showing a method of measuring a maximum bending amount of the hot extruded material for a cylindrical sputtering target.

FIG. 3 is a flow chart showing a method of manufacturing a hot extruded material for a cylindrical sputtering target and a method of manufacturing a cylindrical sputtering target according to an embodiment of the present invention.

### BEST MODE FOR CARRYING OUT THE INVENTION

Hereinafter, a hot extruded material for a cylindrical sputtering target according to an embodiment of the present invention will be described with reference to the accompanying drawings.

A hot extruded material 10 for a cylindrical sputtering target according to the embodiment is a material of a cylindrical sputtering target that is used for forming a thin film (wiring film) formed of copper such as a glass substrate by sputtering.

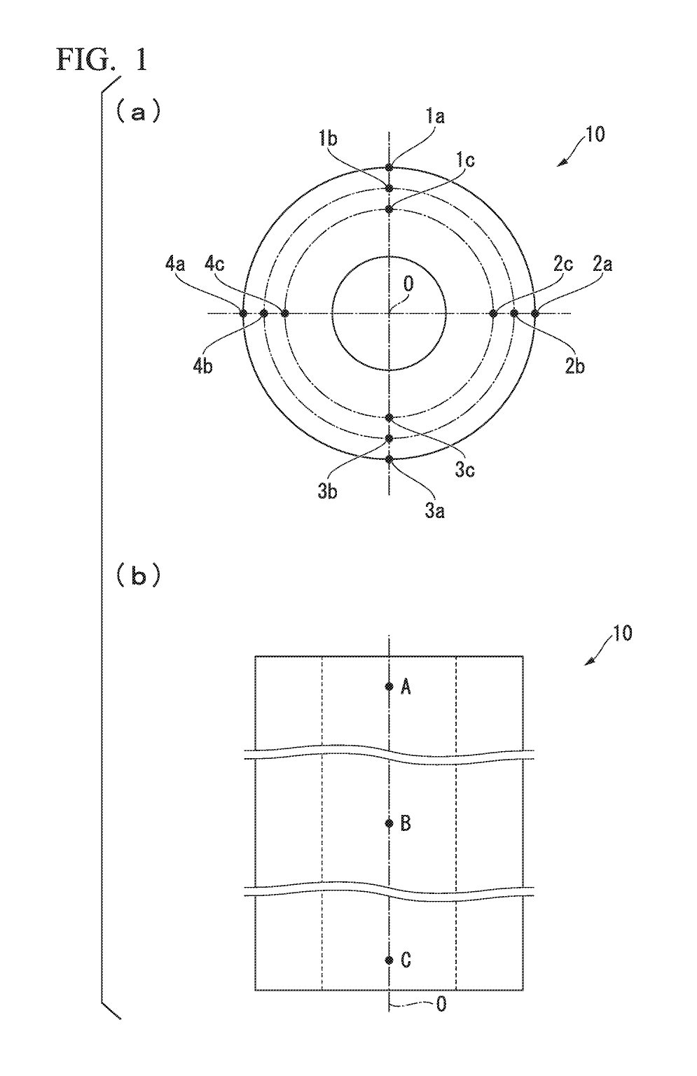

The hot extruded material 10 for a cylindrical sputtering target has a cylindrical shape as shown in FIG. 1, in which, for example, an outer diameter D is in a range of 140 mm≤D≤200 mm, an inner diameter d is in a range of 80 mm≤d≤140 mm, and a length L in the axis direction is in a range of 900 mm≤L×4000 mm. In addition, the thickness of the hot extruded material 10 for a cylindrical sputtering target (a difference between the outer diameter D and the inner diameter d: D−d) is in a range of 10 mm≤D−d≤90 mm.

An outer peripheral surface of the hot extruded material 10 for a cylindrical sputtering target is a sputtering surface of a cylindrical sputtering target.

In a composition of the hot extruded material 10 for a cylindrical sputtering target, a purity of copper is in a range of 99.99 mass % to 99.9995 mass %, an Al content is 0.5 mass ppm or lower, a Si content is 1 mass ppm or lower, a C content is 1 mass ppm or lower, an O content is 2 mass ppm or lower, a H content is 1 mass ppm or lower, and a S content is 5 mass ppm or lower.

Further, in the embodiment, a total content of one element or two or more elements selected from the group consisting of Ag, As, Pb, Sb, Bi, Cd, Sn, Ni, and Fe is in a range of 10 mass ppm to 50 mass ppm.

In the hot extruded material 10 for a cylindrical sputtering target according to the embodiment, as shown in FIG. 1, an average crystal grain size measured at 36 positions in total is in a range of 10 μm to 110 μm and a Vickers hardness measured at the 36 positions in total is in a range of 40 Hv to 100 Hv, the 36 positions being selected by obtaining three cross-sections perpendicular to an axis O direction from one end portion (A), an intermediate portion (B), and another end portion (C) in the axis O direction, setting four positions (1, 2, 3, 4) in a peripheral direction from each of the three cross-sections, and setting three positions in each of the four positions, the three positions including a surface part (a), a radially ¼ position (b) from the surface part, and a radially ½ position (c) from the surface part. In each of the 36 positions, regarding crystal grains in a 800×800×800 μm region, average cut lengths of three axes parallel to and perpendicular to the axis O direction were measured using an optical microscope according to JIS H 0501:1986 (cut method), and an average value thereof was obtained.

In the embodiment, the one end portion and the other portion in the axis O direction are positions at a distance of 100 mm from respective end surfaces thereof toward the center of the hot extruded material 10 for a cylindrical sputtering target in the axis O direction. In addition, the intermediate portion is a center position of the length in the axis O direction.

In addition, in the hot extruded material 10 for a cylindrical sputtering target according to the embodiment, a weight ratio of acid-insoluble residues is 1.5 mass ppm or lower, and the number of acid-insoluble residues having a grain size of 5 μm or more is 15000 residues/Cu 1 g or less.

The evaluation of the acid-insoluble residues is performed in the following procedure.

First, a predetermined amount (for example, 100 g) of a sample is obtained from the hot extruded material 10 for a cylindrical sputtering target having a washed surface and is heated and dissolved in a heated nitric acid solution. The solution is cooled to room temperature and is filtered through a filter to collect residues.

The filter in which the residues are collected is weighed to measure the residue mass of the residues. A ratio of the weight of the residues to the weight of the dissolved sample is calculated. In this way, the amount (weight ratio) of the acid-insoluble residues obtained by heating and dissolving hot extruded material 10 for a cylindrical sputtering target in the nitric acid solution is measured.

Next, the filter in which the residues are collected is observed using a scanning electron microscope to obtain an SEM image. The SEM image is analyzed to measure the sizes and number of acid-insoluble residues. The number of acid-insoluble residues having a grain size of 5 μm or more is obtained.

In this way, in the hot extruded material 10 for a cylindrical sputtering target, the number of acid-insoluble residues having a grain size of 5 μm or more per 1 g of Cu is measured.

Further, in the hot extruded material 10 for a cylindrical sputtering target according to the embodiment, a maximum bending amount is 1.5 mm or less.

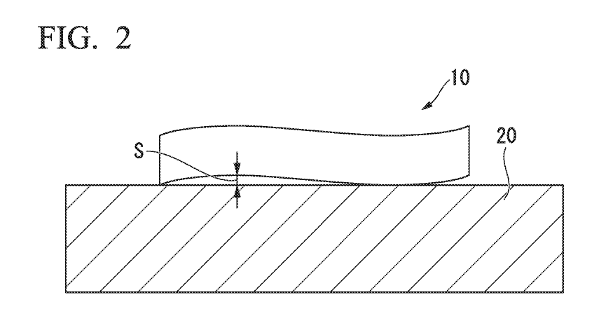

The maximum bending amount is measured as follows. As shown in FIG. 2, the hot extruded material 10 for a cylindrical sputtering target is disposed on a horizontal and flat surface plate 20 such that the axis O of the hot extruded material 10 for a cylindrical sputtering target is parallel to a surface of the surface plate 20. In this state, a maximum value of a clearance S with the surface plate 20 is measured using a clearance gauge. This measurement of the clearance S is performed at four positions at an interval of 90° along the peripheral direction of the hot extruded material 10 for a cylindrical sputtering target, and an average value thereof is set as “maximum bending amount”.

Hereinafter, regarding the hot extruded material 10 for a cylindrical sputtering target according to the embodiment, the reason why the composition, the average crystal grain size, the Vickers hardness, the weight ratio and number of acid-insoluble residues, and the maximum bending amount are limited as described above will be described.

### (Purity of Copper: 99.99 Mass % to 99.9995 Mass %)

In a case where a wiring film (copper film) is formed by sputtering, it is preferable that impurities be reduced as much as possible to suppress abnormal discharge (arcing). In a case where the purity of copper is lower than 99.99 mass %, abnormal discharge frequently occurs due to impurities such that a film may not be stably formed. On the other hand, in a case where the purity of copper is higher than 99.9995 mass %, a complicated purification treatment is necessary, and a significant increase in manufacturing costs can be suppressed.

Due to the above-described reasons, in the embodiment, the purity of copper is set in a range of 99.99 mass % to 99.9995 mass %. In order to suppress the occurrence of abnormal discharge, the lower limit of the purity of copper is preferably 99.993 mass % or higher and more preferably 99.995 mass % or higher. In addition, in order to further suppress a significant increase in manufacturing costs, the upper limit of the purity of copper is preferably 99.9990 mass % or lower and more preferably 99.9985 mass % or lower.

The purity of copper in the embodiment is a numerical value excluding gas components such as O, H, N, S, and C.

That is, the contents of O, H, N, S, and C are measured using the following methods of O: inert gas fusion-infrared absorption method, H inert gas fusion-thermal conductivity method, N: inert gas fusion-thermal conductivity method, S: glow-discharge mass spectrometry, and C: combustion-infrared absorption method. In a case where the purity of copper is calculated, the contents of O, H, N, S, and C are not reduced, and the contents other elements are reduced to calculate the purity of copper.

### (Al: 0.5 Mass Ppm or Lower)

Al is an element that is likely to form an oxide, a carbide, a nitride, or the like, and thus tends to remain as foreign matter in the sputtering target.

Therefore, in the embodiment, by limiting the Al content to be 0.5 mass ppm or lower, even in a case where the purity of Cu is 99.99 mass % or higher, abnormal discharge (arcing) during film formation is suppressed. The Al content is more preferably 0.2 mass ppm or lower. The lower limit value of the Al content is not limited, and is preferably 0.001 mass ppm and more preferably 0 mass ppm. The Al content is measured using a glow-discharge mass spectrometer (VG-9000, manufactured by VG Elemental) according to the analytical procedure of ASTM.

### (Si: 1 Mass Ppm or Lower)

Si is an element that is likely to form an oxide, a carbide, a nitride, or the like, and thus tends to remain as foreign matter in the sputtering target.

Therefore, in the embodiment, by limiting the Si content to be 1 mass ppm or lower, even in a case where the purity of Cu is 99.99 mass % or higher, abnormal discharge (arcing) during film formation is suppressed. The Si content is more preferably 0.8 mass ppm or lower. The lower limit value of the Si content is not limited, and is preferably 0.001 mass ppm and more preferably 0 mass ppm. The Si content is measured using a glow-discharge mass spectrometer (VG-9000, manufactured by VG Elemental) according to the analytical procedure of ASTM.

### (C: 1 Mass Ppm or Lower)

C reacts with another impurity element to form a carbide and is likely to remain as foreign matter in the sputtering target. In addition, C is likely to remain in the sputtering target even when used as a single substance, and thus may cause abnormal discharge (arcing) to occur.

Therefore, in the embodiment, by limiting the C content to be 1 mass ppm or lower, abnormal discharge (arcing) during film formation is suppressed. The C content is more preferably 0.8 mass ppm or lower. The lower limit value of the C content is not limited, and is preferably 0.1 mass ppm and more preferably 0 mass ppm. The C content is measured using CSLS 600 (manufactured by LECO) according to a combustion-infrared absorption method (JIS Z 2615).

### (O: 2 Mass Ppm or Lower/H: 1 Mass Ppm or Lower)

In a case where a film is formed using the sputtering target, sputtering is performed in a vacuum atmosphere. Therefore, in a case where large amounts of the gas components are present, the degree of vacuum decreases during film formation, which may induce abnormal discharge (arcing). In addition, particles are formed due to abnormal discharge, and thus the quality of a high-purity copper film may deteriorate.

Therefore, in the embodiment, the O content is limited to be 2 mass ppm or lower, and the H content is limited to be 1 mass ppm or lower. The O content is more preferably 1 mass ppm or lower, and the H content is more preferably 0.8 mass ppm or lower. The lower limit value of the O content is not limited, and is preferably 0.5 mass ppm and more preferably 0 mass ppm. The O content is measured using TCEN 600 (manufactured by LECO) according to an inert gas fusion-infrared absorption method (JIS H 1067). The lower limit value of the H content is not limited, and is preferably 0.5 mass ppm and more preferably 0 mass ppm. The H content is measured using RHEN 602 (manufactured by LECO) according to an inert gas fusion-thermal conductivity method (JIS Z 2614).

### (S: 5 Mass Ppm or Lower)

S is an element that reacts with another impurity element to form a sulfide and is likely to remain as foreign matter in the sputtering target. In addition, in a case where S is present as a single substance, S is gasified and ionized during film formation such that the degree of vacuum decreases, which may induce abnormal discharge (arcing).

Therefore, in the embodiment, the S content is limited to be 5 mass ppm or lower. The S content is more preferably 4 mass ppm or lower. The lower limit value of the S content is not limited, and is preferably 0.01 mass ppm and more preferably 0 mass ppm. The S content is measured using a glow-discharge mass spectrometer (VG-9000, manufactured by VG Elemental) according to the analytical procedure of ASTM.

(Total Content of One Element or Two or More Elements Selected from Group Consisting of Ag, As, Pb, Sb, Bi, Cd, Sn, Ni, and Fe: 10 Mass Ppm to 50 Mass Ppm)

The above-described elements Ag, As, Pb, Sb, Bi, Cd, Sn, Ni, and Fe act to reduce the crystal grain size. On the other hand, in a case where large amounts of the above-described elements are present, a large amount of particles are formed during film formation, and a film may not be stably formed. The content of the above-described elements is determined by optionally adjusting the addition amounts of the elements Therefore, in the hot extruded material 10 for a cylindrical sputtering target according to the embodiment, in order to reduce the crystal grain size, the total content of the above-described elements is preferably in a range of 10 mass ppm to 50 mass ppm. In order to reliably obtain the effect of reducing the crystal grain size, the lower limit of the total content of one element or two or more elements selected from the group consisting of Ag, As, Pb, Sb, Bi, Cd, Sn, Ni, and Fe is preferably 15 mass ppm or higher and more preferably 20 mass ppm or higher. In addition, in order to reliably suppress particle formation, the upper limit of the total content of one element or two or more elements selected from the group consisting of Ag, As, Pb, Sb, Bi, Cd, Sn, Ni, and Fe is preferably 45 mass ppm or lower and more preferably 40 mass ppm or lower.

The content of Ag, As, Pb, Sb, Bi, Cd, Sn, Ni, and Fe is measured using a glow-discharge mass spectrometer (VG-9000, manufactured by VG Elemental) according to the analytical procedure of ASTM.

### (Average Crystal Grain Size: 10 μm to 110 μm)

The sputtering rate varies depending on crystal orientations. Therefore, as sputtering progresses, unevenness corresponding to crystal grains is formed on the sputtering surface due to a variation in sputtering rate.

In a case where the average crystal grain size is more than 110 μm, unevenness formed on the sputtering surface becomes significant, electric charges are concentrated on protruded portions, and abnormal discharge is likely to occur. On the other hand, in a case where the average crystal grain size is less than 10 μm, the manufacturing costs significantly increase.

Therefore, in the embodiment, the average crystal grain size is limited to be in a range of 10 min to 110 μm. In order to reliably suppress the unevenness of the sputtering surface and to reliably suppress abnormal discharge as sputtering progresses, the average crystal grain size is preferably 100 μm or less and more preferably 80 μm or less. In addition, in order to suppress a significant increase in manufacturing costs, the average crystal grain size is preferably 20 μm or more and more preferably 30 μm or more.

### (Vickers Hardness: 40 Hv to 100 Hv)

In the hot extruded material 10 for a cylindrical sputtering target according to the embodiment, in a case where the Vickers hardness is higher than 100 Hv, internal strains in crystal grains increase, the formation of secondary electrons during sputtering is unstable, and a film may not be stably formed. In addition, due to internal strains, the sputtering rate varies, unevenness is formed on the sputtering surface, and thus the number of times of micro arc discharge may increase. On the other hand, in a case where the Vickers hardness is lower than 40 Hv, the crystal grain size increases. Therefore, as sputtering progresses, unevenness is formed on the sputtering surface, and abnormal discharge is likely to occur.

Due to the above-described reasons, in the embodiment, the Vickers hardness is limited to be in a range of 40 Hv to 100 Hv. In order to suppress an increase in crystal grain size and to reliably suppress abnormal discharge, the lower limit of the Vickers hardness is preferably 45 Hv or higher and more preferably 50 Hv or higher. In addition, in order to make the sputtering rate uniform and to reliably suppress unevenness in thickness and micro arc discharge, the upper limit of the Vickers hardness of the sputtering surface is preferably 95 Hv or lower, and more preferably 90 Hv or lower.

The Vickers hardness can be measured at all the 36 positions, which are the same as that in the measurement of the average crystal grain size, using a Vickers hardness tester according to JIS Z 2244.

### (Weight Ratio and Number of Acid-Insoluble Residues)

In the hot extruded material 10 for a cylindrical sputtering target according to the embodiment, in a case where acid-insoluble residues are present, abnormal discharge is likely to occur due to the acid-insoluble residues. In particular, electric charges are concentrated on residues having a grain size of 5 μm or more, and abnormal discharge may occur due to the residues.

Therefore, in the embodiment, the weight ratio of acid-insoluble residues is limited to be 1.5 mass ppm or lower, and the number of acid-insoluble residues having a grain size of 5 μm or more is limited to be 15000 residues/Cu 1 g or less.

In order to further suppress the occurrence of abnormal discharge, the weight ratio of acid-insoluble residues is preferably 1.2 mass ppm or lower, and the number of acid-insoluble residues having a grain size of 5 μm or more is preferably 12000 residues/Cu 1 g or less.

The lower limit value of the weight ratio of residues is not particularly limited and may be 0.5 mass ppm, and the lower limit value of the number of acid-insoluble residues having a grain size of 5 μm or more may be 500 residues/Cu 1 g.

### (Maximum Bending Amount)

In the hot extruded material 10 for a cylindrical sputtering target according to the embodiment, in a case where the maximum bending amount increases, the cutting allowance during cutting increases, it may be difficult to manufacture a thick cylindrical sputtering target. In addition, the yield decreases, and thus the manufacturing costs may significantly increase.

Therefore, in the embodiment, the maximum bending amount is limited to be 1.5 mm or less. In order to reliably cut the cutting allowance during cutting, the maximum bending amount is preferably 1.2 mm or less and more preferably 1.0 mm or less. The lower limit value of the maximum bending amount is not particularly limited and may be 0.1 mm.

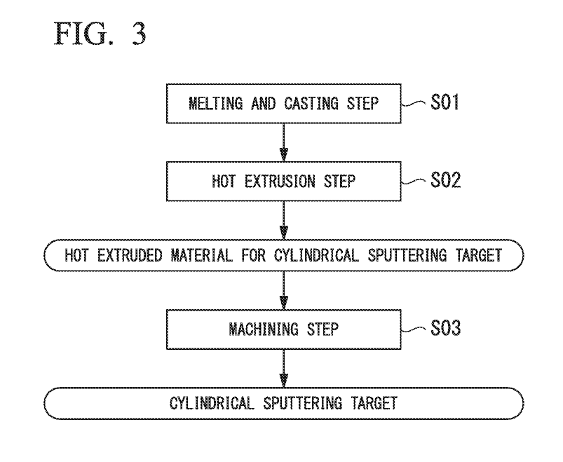

Next, a method of manufacturing the hot extruded material 10 for a cylindrical sputtering target having the above-described configuration, and a method of manufacturing a cylindrical sputtering target using the hot extruded material 10 for a cylindrical sputtering target will be described with reference to a flowchart of FIG. 3.

In the embodiment, the method includes: a melting and casting step S01 of obtaining an ingot having a predetermined composition; a hot extrusion step S02 of performing hot extrusion on the obtained ingot to manufacture the hot extruded material 10 for a cylindrical sputtering target; and a machining step S03 of performing machining on the obtained hot extruded material 10 for a cylindrical sputtering target.

In the melting and casting step S01, a cylindrical ingot is continuously cast using various casting machines such as a vertical continuous casting machine, a horizontal continuous casting machine, or a semi-continuous casting machine and is cut into a predetermined length.

In the melting and casting step S01, in order to reduce the content of impurity elements such as Al or Si, oxygen is supplied into a trough through which molten copper passes to produce oxides and to remove the impurity elements as solids, and then the molten copper is deoxidized. In addition, in the embodiment, the ingot as a product is obtained when the behavior of impurity elements is stable after 5 t from the start of casting.

In the hot extrusion step S02, extrusion is performed on the cylindrical ingot at a predetermined temperature to manufacture the hot extruded material 10 for a cylindrical sputtering target.

In the embodiment, the hot extrusion temperature is set in a range of 500° C. to 600° C. The hot extrusion temperature is more preferably 520° C. to 580° C. In addition, after the extrusion, soaking is performed in a soaking zone including heating devices such as a heater, and then rapid cooling is performed.

In the soaking zone, a holding temperature is in a range of 530° C. to 600° C., and a holding time is set in a range of 1 min to 15 min. The holding temperature is preferably 540° C. to 580° C., and the holding time is 2 min to 10 min. In addition, during the rapid cooling, a cooling rate is set in a range of 30° C./min to 60° C./min. The cooling rate is more preferably 35° C./min to 55° C./min.

In this way, the hot extruded material 10 for a cylindrical sputtering target according to the embodiment is obtained.

In addition, in the embodiment, machining is performed on the hot extruded material 10 for a cylindrical sputtering target to manufacture a cylindrical sputtering target having a predetermined size. That is, in the embodiment, the cylindrical sputtering target is manufactured without performing cold working on the hot extruded material 10 for a cylindrical sputtering target.

The cylindrical sputtering target rotates around the axis during use in a sputtering device, and an outer peripheral surface thereof is used as a sputtering surface.

In the hot extruded material 10 for a cylindrical sputtering target according to the embodiment having the above-described configuration, as shown in FIG. 1, an average crystal grain size measured at 36 positions in total is in a range of 10 μm to 110 μm and a Vickers hardness measured at the 36 positions in total is in a range of 40 Hv to 100 Hv, the 36 positions being selected by obtaining three cross-sections perpendicular to an axis O direction from one end portion (A), an intermediate portion (B), and another end portion (C) in the axis O direction, setting four positions (1, 2, 3, 4) in a peripheral direction from each of the three cross-sections, and setting three positions in each of the four positions, the three positions including a surface part (a), a radially ¼ position (b) from the surface part, and a radially ½ position (c) from the surface part. Therefore, there is no variation in crystal grain size and Vickers hardness, and the hot extruded material 10 for a cylindrical sputtering target can be used as a cylindrical sputtering target only after performing machining thereon.

As described above, cold working (expansion) is not necessary. Therefore, a thick cylindrical sputtering target can be obtained, and the lifetime thereof can be increased.

In addition, in the embodiment, the Al content is 0.5 mass ppm or lower, the Si content is 1 mass ppm or lower, the C content is 1 mass ppm or lower, the O content is 2 mass ppm or lower, the H content is 1 mass ppm or lower, and the S content is 5 mass ppm or lower. Therefore, the occurrence of abnormal discharge caused by foreign matter including the impurities can be suppressed, and a film can be stably formed.

In addition, in the hot extruded material 10 for a cylindrical sputtering target according to the embodiment, the total content of one element or two or more elements selected from the group consisting of Ag, As, Pb, Sb, Bi, Cd, Sn, Ni, and Fe is 10 mass ppm or higher. Therefore, the crystal grain size can be reduced, and a variation in average crystal grain size and Vickers hardness can be further suppressed.

On the other hand, the total content of one element or two or more elements selected from the group consisting of Ag, As, Pb, Sb, Bi, Cd, Sn, Ni, and Fe is limited to be 50 mass ppm or lower. Therefore, the occurrence of abnormal discharge caused by the elements can be reliably reduced.

Further, in the hot extruded material 10 for a cylindrical sputtering target according to the embodiment, the weight ratio of acid-insoluble residues is 1.5 mass ppm or lower, and the number of acid-insoluble residues having a grain size of 5 μm or more is limited to be 15000 residues/Cu 1 g or less. Therefore, particle formation can be suppressed during film formation.

In addition, in the hot extruded material 10 for a cylindrical sputtering target according to the embodiment, the outer diameter is 140 mm to 200 mm, the inner diameter is 80 mm to 140 mm, and the length is 900 mm to 4000 mm. Therefore, a relatively thick and long-life cylindrical sputtering target can be manufactured.

Further, the maximum bending amount is 1.5 mm or less. Therefore, a reduction in thickness caused by cutting can be suppressed.

Further, the method of manufacturing a cylindrical sputtering target according to the embodiment includes the machining step S03 of performing machining on the obtained hot extruded material 10 for a cylindrical sputtering target according to the embodiment. In this method, a cooling step is not necessary, and the manufacturing costs can be reduced. In addition, bending or warping caused by a cooling step does not occur, the inner peripheral surface and the outer peripheral surface of the hot extruded material 10 for a cylindrical sputtering target is not cut more than necessary, and thus a thick cylindrical sputtering target can be obtained.

Hereinabove, the embodiment of the present invention has been described. However, the present invention is not limited to the embodiment, and various modifications can be made within a range not departing from the technical ideas of the present invention.

For example, in the embodiment, the size of the hot extruded material for a cylindrical sputtering target is not limited to that of the embodiment and may be another size.

### Examples

Hereinafter, the results of an experiment for verifying the effectiveness of the present invention will be described.

First, in a vertical continuous casting machine, a cylindrical ingot formed of copper having a composition shown in Table 1 was obtained by using electrolytic copper having a purity of 99.99 mass % or higher as a raw material. By analyzing the components of the electrolytic copper as a raw material before melting and casting, the contents of Ag, As, Pb, Sb, Bi, Cd, Sn, Ni, and Fe were adjusted. In addition, Ag, As, Pb, Sb, Bi, Cd, Sn, Ni, and Fe were optionally added to molten alloy to adjust the contents thereof. In Examples 1-18 and Comparative Example 1, impurities such as Al or Si were removed as described above. On the other hand, in Comparative Examples 2 and 3, impurities were not removed.

The ingot was heated to a treatment temperature shown in Table 2 to perform hot extrusion. As a result, a hot extruded material for a cylindrical sputtering target (outer diameter: 173 mm, inner diameter: 125 mm) was obtained.

In the Example 1-18, after the extrusion, the ingot was caused to pass through a soaking zone (holding temperature: 580° C., holding time: 5 min) and then was cooled at a cooling rate shown in Table 2. On the other hand, in Comparative Example 1-3, a soaking zone was not provided, and after the extrusion, the ingot was cooled at a cooling rate shown in Table 2.

Machining was performed on the hot extruded material for a cylindrical sputtering target obtained as described above. As a result, a cylindrical sputtering target (outer diameter: 170 mm, inner diameter 120 mm, length: 600 mm) was manufactured.

Regarding the hot extruded material for a cylindrical sputtering target and the cylindrical sputtering target, the following evaluations were performed.

### <Analysis of Impurity Elements and Respective Elements>

Impurity elements (Al, Si, and S) other than 0, H, and C and respective elements including Ag, As, Pb, Sb, Bi, Cd, Sn, Ni, and Fe were analyzed using a glow-discharge mass spectrometer (VG-9000, manufactured by VG Elemental). The analysis was performed according to the analytical procedure of ASTM.

The analysis of O was performed using an inert gas fusion-infrared absorption method (JIS H 1067). Specifically, the analysis was performed using TCEN 600 (manufactured by LECO) according to JIS Z 2613.

The analysis of H was performed using an inert gas fusion-thermal conductivity method. Specifically, the analysis was performed using RHEN 602 (manufactured by LECO) according to JIS Z 2614.

The analysis of C was performed using a combustion-infrared absorption method. Specifically, the analysis was performed using CSLS 600 (manufactured by LECO) according to JIS Z 2615.

The purity of copper shown in Table 1 is a value obtained by subtracting the sum of the contents of the respective elements other than gas components, the Al content and the Si content from 100 mass % of the obtained hot extruded material for a cylindrical sputtering target.

### <Average Crystal Grain Size of Hot Extruded Material for Cylindrical Sputtering Target>

As shown in FIG. 1, a crystal grain size was measured at 36 positions in total, and an average crystal grain size thereof was calculated, the 36 positions being selected by obtaining three cross-sections perpendicular to an axis direction from one end portion (A), an intermediate portion (B), and another end portion (C) in the axis direction, setting four positions (1, 2, 3, 4) in a peripheral direction from each of the three cross-sections, and setting three positions in each of the four positions, the three positions including a surface part (a), a radially ¼ position (b) from the surface part, and a radially ½ position (c) from the surface part. The crystal grain size was measured according to JIS H0501:1986 (cutting method) after observing a microstructure with an optical microscope. The evaluation results are shown in Table 2.

### <Vickers Hardness of Hot Extruded Material for Cylindrical Sputtering Target>

As shown in FIG. 1, a Vickers hardness was measured at 36 positions in total, and an average value thereof was calculated, the 36 positions being selected by obtaining three cross-sections perpendicular to an axis direction from one end portion (A), an intermediate portion (B), and another end portion (C) in the axis direction, setting four positions (1, 2, 3, 4) in a peripheral direction from each of the three cross-sections, and setting three positions in each of the four positions, the three positions including a surface part (a), a radially ¼ position (b) from the surface part, and a radially ½ position (c) from the surface part. The Vickers hardness was measured using a Vickers hardness tester according to JIS Z 2244. The evaluation results are shown in Table 2.

### <Acid-Insoluble Residues>

A measurement sample was etched with nitric acid to remove impurities attached to the surface. Next, 100 g of the sample was weighed. This sample was heated and dissolved in a nitric acid solution. The heating temperature was 60° C. This operation was repeated. Next, the sample was cooled to room temperature and was filtered through a filter to collect residues.

The filtering was performed using a polycarbonate filter (pore size: 0.4 μm). The polycarbonate filter in which the residues were collected was weighed using an electronic balance in a clean room to measure the residue mass of the residues, and a weight ratio of acid-insoluble residue was calculated. The evaluation results are shown in Table 2.

In addition, a grain size distribution of the acid-insoluble residue was measured. The filter in which the residues were collected was observed using a scanning electron microscope to obtain an SEM image. The image was input to a personal computer and was binarized and analyzed using image analysis software (WinRoof software). The projected area of a residue was measured, and the diameter (equivalent circle diameter) of a circle having the same area as the projected area was calculated. This equivalent circle diameter was used as a grain size of the residue. The number of acid-insoluble residues having a grain size of 5 μm or more was measured. The evaluation results are shown in Table 2.

### <Sputtering Test>

Using the obtained cylindrical sputtering target, a sputtering test was performed under the following conditions, and the number of times of abnormal discharge was counted using an arcing counter equipped in a sputtering device. The sputtering test was performed under two conditions of “Ar gas” and “N₂ gas” regarding an atmosphere gas. The evaluation results are shown in Table 2.

Power source: direct current type

Sputtering power: 600 W

Sputtering pressure: 0.2 Pa

Sputtering time: 8 hours

Peak vacuum degree: 4×10⁻⁵ Pa or lower

Atmosphere gas composition: Ar gas/N₂ gas

### <Tearing>

In a case where machining was performed on the hot extruded material for a cylindrical sputtering target, the surface was observed by visual inspection to determine whether or not scratches or unevenness was formed on the surface. In a case where a scratch or a torn portion was not necessary to be repaired and had a depth of 0.5 mm or less and had a length of less than 5 mm or less, the cylindrical sputtering target was evaluated as A. In a case where a scratch or a torn portion had a depth of more than 0.5 mm and had a length of more than 5 mm, the cylindrical sputtering target was evaluated as B. The evaluation results are shown in Table 2.

### <Maximum Bending Amount>

According to the embodiment and the method shown in FIG. 2, the maximum bending amount of the hot extruded material for a cylindrical sputtering target was measured. The evaluation results are shown in Table 2.

TABLE 1

| | | Impurities and Gas | | | | | | | | | | | | | | | |
|---|---|---|---|---|---|---|---|---|---|---|---|---|---|---|---|---|---|
| | | Components (mass ppm) | | | | | | Contents of Respective Elements (mass ppm) | | | | | | | | | Purity of Copper |
| | | Al | Si | C | 0 | H | S | Ag | As | Pb | Bi | Cd | Sn | Ni | Fe | Total Content | (mass %) |
| Example | 1 | 0.04 | 0.5 | 0.5 | 2.0 | 0.9 | 3 | 0.1 | <1 | <1 | <1 | <1 | <1 | 2 | 2 | 4.1 | 99.9995 |
| | 2 | 0.14 | 0.2 | 0.3 | <0.5 | <0.5 | 4 | 0.2 | <1 | <1 | <1 | <1 | <1 | 3 | 2 | 5.2 | 99.9994 |
| | 3 | 0.08 | 0.1 | 0.2 | 1.5 | 1.0 | 3 | 0.5 | <1 | <1 | <1 | <1 | <1 | 4 | 5 | 9.5 | 99.9990 |
| | 4 | 0.48 | 0.5 | 1.0 | <0.5 | <0.5 | 3 | 20 | 1 | 10 | 1 | 2 | 10 | 10 | 20 | 74 | 99.9925 |
| | 5 | 0.02 | 0.5 | 0.5 | <0.5 | <0.5 | 4 | 10 | <1 | <1 | <1 | <1 | <1 | 1 | 1 | 12 | 99.9987 |
| | 6 | 0.05 | 1.0 | 0.5 | <0.5 | <0.5 | 3 | 13 | 11 | 2 | 4 | <1 | <1 | 1 | 1 | 32 | 99.9966 |
| | 7 | 0.50 | 1.0 | 0.5 | <0.5 | <0.5 | 3 | 13 | <1 | 11 | <1 | <1 | <1 | 1 | 1 | 26 | 99.9972 |
| | 8 | 0.06 | 0.9 | 0.5 | <0.5 | 1.0 | 4 | 13 | 3 | 2 | 8 | <1 | <1 | 1 | 1 | 28 | 99.9971 |
| | 9 | 0.12 | 0.7 | 0.5 | <0.5 | <0.5 | 4 | 13 | 3 | 2 | <1 | 9 | <1 | 1 | 1 | 29 | 99.9970 |
| | 10 | 0.15 | 0.6 | 0.5 | <0.5 | <0.5 | 3 | 13 | <1 | <1 | <1 | <1 | 7 | 1 | 1 | 22 | 99.9977 |
| | 11 | 0.04 | 0.6 | 0.5 | 2.0 | 0.8 | 3 | 13 | <1 | <1 | <1 | <1 | <1 | 13 | 7 | 33 | 99.9966 |
| | 12 | 0.50 | 0.9 | 1.0 | 1.6 | 0.8 | 4 | 13 | <1 | <1 | <1 | <1 | <1 | <1 | 9 | 22 | 99.9976 |
| | 13 | 0.12 | 0.5 | 0.5 | <0.5 | <0.5 | 5 | 12 | <1 | <1 | <1 | <1 | <1 | 13 | 12 | 37 | 99.9962 |
| | 14 | 0.12 | 0.5 | 0.5 | <0.5 | <0.5 | 3 | 13 | <1 | <1 | <1 | <1 | <1 | 1 | 1 | 15 | 99.9984 |
| | 15 | 0.15 | 0.2 | 0.5 | <0.5 | <0.5 | 3 | 12 | <1 | <1 | <1 | <1 | <1 | 1 | 1 | 14 | 99.9985 |
| | 16 | 0.09 | 0.1 | 0.5 | <0.5 | <0.5 | 3 | 14 | <1 | <1 | <1 | <1 | <1 | 1 | 1 | 16 | 99.9983 |
| | 17 | 0.07 | 0.8 | 0.5 | <0.5 | <0.5 | 5 | 15 | <1 | <1 | <1 | <1 | <1 | 1 | 1 | 17 | 99.9982 |
| | 18 | 0.10 | 1.0 | 0.5 | <0.5 | <0.5 | 3 | 13 | <1 | <1 | <1 | <1 | <1 | 1 | 1 | 15 | 99.9983 |
| Comparative | 1 | 1.5 | 1.5 | 2.0 | 10.0 | 1.4 | 9 | 15 | <1 | 7 | <1 | <1 | <1 | 9 | 10 | 41 | 99.9955 |
| Example | 2 | 2.0 | 1.4 | 2.0 | 5.2 | 1.5 | 8 | 15 | <1 | 8 | <1 | <1 | <1 | 10 | 10 | 43 | 99.9953 |
| | 3 | 2.0 | 1.5 | 2.0 | 4.1 | 1.3 | 10 | 15 | <1 | 5 | <1 | <1 | 5 | 7 | 10 | 42 | 99.9954 |

TABLE 2

| | | | | | | | | Acid-Insoluble | | | | | |
|---|---|---|---|---|---|---|---|---|---|---|---|---|---|
| | | | | | | | | Residues | | | | | |
| | | | | | | | | | Number of | | | | |
| | | Casting | | | | | | | acid- | Number of Times | | | |
| | | Step | Extrusion Step | | | | Vickers | Weight | insoluble | of Abnormal | | | Maximum |
| | | Removal | Treatment | | Cooling | Crystal | Hard- | Ratio | residues | Discharge | | | Bending |
| | | of | Temperature | Soaking | Rate | Grain Size | ness | mass | Residues/ | Ar | N₂ | | Amount |
| | | Impurities | ° C. | Zone | ° C./sec | μm | Hv | ppm | Cu 1 g | times/h | times/h | Tearing | mm |
| Examples | 1 | Performed | 510 | Provided | 35 | 84 | 69 | 0.8 | 12000 | 1 | 2 | A | 0.7 |
| | 2 | Performed | 580 | Provided | 35 | 89 | 65 | 0.6 | 8000 | 1 | 1 | A | 0.7 |
| | 3 | Performed | 550 | Provided | 40 | 60 | 70 | 0.3 | 4500 | 1 | 2 | A | 0.7 |
| | 4 | Performed | 510 | Provided | 42 | 24 | 90 | 0.4 | 4000 | 2 | 3 | A | 0.7 |
| | 5 | Performed | 520 | Provided | 38 | 29 | 86 | 0.5 | 4200 | 0 | 0 | A | 0.8 |
| | 6 | Performed | 540 | Provided | 48 | 45 | 81 | 0.4 | 4000 | 0 | 0 | A | 0.7 |
| | 7 | Performed | 550 | Provided | 55 | 51 | 71 | 0.8 | 7900 | 0 | 0 | A | 0.6 |
| | 8 | Performed | 560 | Provided | 51 | 79 | 60 | 0.6 | 8400 | 0 | 0 | A | 0.7 |
| | 9 | Performed | 580 | Provided | 49 | 89 | 55 | 0.5 | 3900 | 0 | 0 | A | 0.7 |
| | 10 | Performed | 590 | Provided | 51 | 98 | 51 | 0.8 | 13000 | 1 | 1 | A | 0.8 |
| | 11 | Performed | 540 | Provided | 39 | 37 | 90 | 0.8 | 12100 | 1 | 1 | A | 0.6 |
| | 12 | Performed | 550 | Provided | 31 | 29 | 59 | 1.2 | 13900 | 2 | 2 | A | 0.7 |
| | 13 | Performed | 550 | Provided | 58 | 27 | 64 | 0.6 | 8300 | 0 | 1 | A | 0.8 |
| | 14 | Performed | 550 | Provided | 55 | 59 | 78 | 0.7 | 9100 | 0 | 1 | A | 0.7 |
| | 15 | Performed | 520 | Provided | 38 | 31 | 95 | 1.0 | 13000 | 1 | 1 | A | 0.7 |
| | 16 | Performed | 520 | Provided | 39 | 35 | 89 | 1.9 | 14500 | 3 | 3 | A | 0.7 |
| | 17 | Performed | 530 | Provided | 39 | 58 | 79 | 0.9 | 21400 | 3 | 4 | A | 0.8 |
| | 18 | Performed | 590 | Provided | 44 | 98 | 49 | 0.6 | 8200 | 0 | 0 | A | 2.3 |
| Comparative | 1 | Performed | 450 | Not | 48 | Since Extrusion could not be Performed, Evaluations were not Performed | | | | | | | |
| Example | | | | Provided | | | | | | | | | |
| | 2 | Not | 750 | Not | 55 | 110 | 40 | 2.0 | 30000 | 121 | 81 | B | 1.2 |
| | | Performed | | Provided | | | | | | | | | |
| | 3 | Not | 800 | Not | 34 | 120 | 32 | 1.9 | 29000 | 112 | 73 | B | 1.9 |
| | | Performed | | Provided | | | | | | | | | |

In Comparative Example 1, the heating temperature in the extrusion step was lower than 450° C., and thus extrusion could not be performed. Therefore, the subsequent evaluations were stopped.

In Comparative Examples 2 and 3, the contents of Al and Si as impurities and the contents of C, O, H, and S as gas components were outside of the ranges of the present invention, the number of acid-insoluble residues was large, and the number of times of abnormal discharge was extremely large. In addition, tearing frequently occurred during cutting.

On the other hand, in all the Examples, the number of times of abnormal discharge was small, and a film could be stably formed. In addition, the occurrence of tearing during cutting was small, and machinability was excellent.

It was verified from the above results that, according to Examples, it is possible to provide a thick and long-life hot extruded material for a cylindrical sputtering target with which abnormal discharge is suppressed such that a film can be stably formed.

### REFERENCE SIGNS LIST

10: HOT EXTRUDED MATERIAL FOR A CYLINDRICAL SPUTTERING TARGET

1. A hot extruded material for a cylindrical sputtering target,
wherein a purity of copper is in a range of 99.99 mass % to 99.9995 mass %,
an Al content is 0.5 mass ppm or lower, a Si content is 1 mass ppm or lower, a C content is 1 mass ppm or lower, an O content is 2 mass ppm or lower, a H content is 1 mass ppm or lower, and a S content is 5 mass ppm or lower, and
an average crystal grain size measured at 36 positions in total is in a range of 10 μm to 110 μm and a Vickers hardness measured at the 36 positions in total is in a range of 40 Hv to 100 Hv, the 36 positions being selected by obtaining three cross-sections perpendicular to an axis direction from one end portion, an intermediate portion, and another end portion in the axis direction, setting four positions in a peripheral direction from each of the three cross-sections, and setting three positions in each of the four positions, the three positions including a surface part, a radially ¼ position from the surface part, and a radially ½ position from the surface part.

2. The hot extruded material for a cylindrical sputtering target according to claim 1,
wherein a total content of one element or two or more elements selected from the group consisting of Ag, As, Pb, Sb, Bi, Cd, Sn, Ni, and Fe is in a range of 10 mass ppm to 50 mass ppm.

3. The hot extruded material for a cylindrical sputtering target according to claim 1,
wherein a weight ratio of acid-insoluble residues is 1.5 mass ppm or lower, and the number of acid-insoluble residues having a grain size of 5 μm or more is 15000 residues/Cu 1 g or less.

4. The hot extruded material for a cylindrical sputtering target according to claim 1,
wherein an outer diameter is 140 mm to 200 mm, an inner diameter is 80 mm to 140 mm, and a length is 900 mm to 4000 mm, and
a maximum bending amount is 1.5 mm or less.

5. A method of manufacturing a cylindrical sputtering target, the method comprising:
a melting and casting step of obtaining an ingot in which a purity of copper is 99.99 mass % to 99.9995 mass %, an Al content is 0.5 mass ppm or lower, a Si content is 1 mass ppm or lower, a C content is 1 mass ppm or lower, an O content is 2 mass ppm or lower, a H content is 1 mass ppm or lower, and a S content is 5 mass ppm or lower;
a hot extrusion step of performing hot extrusion on the ingot to obtain a hot extruded material for a cylindrical sputtering target; and
a machining step of performing machining on the hot extruded material for a cylindrical sputtering target.
